(19) United States
(12) Patent Application Publication
(10) Pub. No.: US 2026/0101571 A1
(43) Pub. Date: Apr. 9, 2026

(54) DEVICE WITH INTEGRATED TRENCH MOSFET AND INTEGRATED TRENCH SCHOTTKY BARRIER DIODE

(71) Applicant: Microchip Technology Incorporated, Chandler, AZ (US)

(72) Inventors: Shesh Mani Pandey, Gilbert, AZ (US); Bruce Odekirk, Portland, OR (US)

(73) Assignee: Microchip Technology Incorporated, Chandler, AZ (US)

(21) Appl. No.: 19/282,772

(22) Filed: Jul. 28, 2025

Related U.S. Application Data
(60) Provisional application No. 63/704,954, filed on Oct. 8, 2024.

(51) Int. Cl. H10D 84/00; H10D 84/01; H10D 62/832

(52) U.S. Cl. CPC H10D 84/146; H10D 84/0109; H10D 62/8325

(57) ABSTRACT

A semiconductor device includes an integrated trench MOSFET and an integrated trench SBD. A method of making such a device is also disclosed. The device includes a volume of semiconductor material including a first end and a second end. The trench MOSFET includes a source at the first end, a drain, a channel extending between the source and the drain, a body adjacent to the source, a first trench extending into the semiconductor material adjacent to the channel, and a gate within the first trench. The trench SBD is located at the first end of the semiconductor material adjacent to and spaced apart from the trench MOSFET, and includes a second trench extending into the semiconductor material and at least in part lined with an SBD material. An electrical terminal connects the source, the body, and the trench SBD and extends into the second trench.

### RELATED APPLICATION

The present U.S. non-provisional patent application is related to and claims priority benefit of an earlier-filed U.S. provisional patent application titled "Device with Integrated Trench MOSFET and Trench Schottky barrier diode," Serial No. 63/704,954, filed October 8, 2024. The entire content of the identified earlier-filed application is incorporated by reference as if fully set forth herein.

### FIELD

The present disclosure relates to semiconductor field-effect transistors and methods of making them, and, more particularly, the various examples described herein concern a device including an integrated trench field-effect transistor and an integrated trench Schottky barrier diode, and a method of making a device including an integrated trench field-effect transistor and an integrated trench Schottky barrier diode.

### BACKGROUND

A metal-oxide-semiconductor field-effect transistor (MOSFET) is an active, voltage-controlled semiconductor device, in which varying an electrical voltage between a gate and a body controls an electrical current flowing through a semiconductor channel between a drain and a source. Applications for MOSFETs include amplifiers, switches, resistors, regulators, oscillators, and choppers. It is generally desirable to improve the performance and reduce the cost of MOSFETs, but it can be difficult to do so.

This background discussion is intended to provide related information, and is not necessarily prior art.

### SUMMARY

Examples provide a device including an integrated trench field-effect transistor (FET) and an integrated trench Schottky barrier diode (SBD), and a method of making a device including an integrated trench FET and an integrated trench SBD. Broadly, examples physically and functionally integrate a trench SFET and a trench SBD into a single, continuous structure. Examples advantageously provide the benefits of improved reverse conduction and lower cost, and the larger diode resulting from the trench structure is advantageously able to handle higher electrical current.

In an example, a device may include a volume of semiconductor material, an integrated trench field-effect transistor (e.g., a trench MOSFET), an integrated trench SBD, and a first electrical terminal. The volume of semiconductor material may include a first end and a second end. The integrated trench FET may include a source located at the first end of the volume of semiconductor material, a drain, a body located adjacent to the source, a body contact located adjacent to the body, a first trench extending into the first end of the volume of semiconductor material, and a gate located within the first trench. The integrated trench SBD may be located at the first end of the volume of semiconductor material adjacent to and spaced apart from the trench FET, and may include a second trench extending into the semiconductor material adjacent to and spaced apart from the gate. An SBD material may line at least part of the second trench. The first electrical terminal may electrically connect the source, the body via the body contact, and the trench SBD and extend into the second trench.

The preceding example may further include any one or more of the following features. The Schottky material and the first electrical terminal may be integrally formed. The Schottky material may occupy a first portion of the second trench, and the first electrical terminal may fill the remaining portion of the trench. The first trench may include a bottom and first and second spaced apart sides that extend between the bottom and the first end of the volume of semiconductor material. The integrated trench field-effect transistor may include a dielectric material lining the bottom and sides of the first trench. The second trench may a bottom and first and second spaced apart sides that extend between the bottom and the first end of the volume of semiconductor material. The Schottky material may line the bottom and one of the sides of the second trench. The first side of the first trench may be spaced apart but adjacent the second trench, and the source, body, and body contact may be located adjacent the second side of the first trench. The second side of the second trench may be spaced apart but adjacent the first side of the first trench. The Schottky material may line the second side of the second trench, and the integrated trench field-effect transistor may include a dielectric material lining the first side the first side of the first trench. The dielectric material may further line the bottom and the second side of the first trench, and the Schottky material may line the bottom of the second trench. The volume of semiconductor material may include an N-type epitaxial semiconductor material, the source may include an N+ material, the drain may include an N+ substrate material, the body may include a P-type material, the body contact may include a P++ material, and the gate may include a doped polysilicon material. The SBD material may be aluminum, titanium, molybdenum, platinum, chromium, or tungsten. The device may further include a second electrical terminal provided on the gate, and a third electrical terminal provided on the drain. The first and second trenches may extend an equal length from the first end of the volume of semiconductor material.

In another example, a method of making a device including an integrated trench FET (e.g., a trench MOSFET) and an integrated trench SBD may include the following operations. A volume of semiconductor material, including a first end and a second end, may be provided. The integrated trench FET may be made by providing a source at the first end of the volume of semiconductor material, providing a drain, providing a body located adjacent to the source, providing a body contact adjacent to the body, etching a first trench extending into the first end of the volume of semiconductor material, and providing a gate within the first trench. The integrated trench SBD may be located at the first end of the volume of semiconductor material adjacent to and spaced apart from trench FET, and may be made by etching a second trench extending into the semiconductor material adjacent to and spaced apart from the gate. The operation of the making the integrated trench SBD may also include lining at least part of the second trench with an SBD material. An electrical terminal may be provided electrically connecting the source, the body via the body contact, and the trench SBD and extending into the second trench.

The preceding example may further include any one or more of the following features. The operation of etching the first and second trenches may include extending the first and second trenches an equal length from the first end of the volume of semiconductor material. The step of etching the first trench may include forming a trench bottom and first and second spaced apart trench sides that extend between the trench bottom and the first end of the volume of semiconductor material, with the first trench side being spaced apart but adjacent the second trench, with the source, body, and body contact being located adjacent the second side of the first trench. The step of etching the second trench may include forming a trench bottom and first and second spaced apart trench sides that extend between the trench bottom and the first end of the volume of semiconductor material, with the second trench side of the second trench being spaced apart but adjacent the first trench side of the first trench. The step of lining the second trench with the Schottky material may include lining the second trench side of the second trench. The step of making the integrated trench field-effect transistor may include lining the first trench side of the first trench with a dielectric material. The Schottky material may occupy a first portion of the second trench, and the operation of providing the electrical terminal may include filling the remaining portion of the second trench with the electrical terminal.

This summary is not intended to identify essential features of the examples, and is not intended to be used to limit the scope of the claims. These and other aspects of the present examples are described below in greater detail.

### DRAWINGS

Examples are described in detail below with reference to the attached drawing figures, wherein:

FIG. 1 is a cross-sectional elevation view of an example of a device including an integrated trench MOSFET and an integrated trench SBD;

FIG. 2 is a flowchart of operations in an example of a method of manufacturing a device including an integrated trench MOSFET and an integrated trench SBD;

FIG. 3A is a cross-sectional elevation view of the result of an operation in the method of FIG. 2, wherein a volume of N-type epitaxial semiconductor material is provided on an N+ substrate drain, and an N+ source, a P-type body, and a P++ body contact are implanted;

FIG. 3B is a cross-sectional elevation view of the result of an operation in the method of FIG. 2, wherein a first trench is etched, a dielectric material is provided lining the first trench, and a doped polysilicon gate is deposited in the first trench;

FIG. 3C is a cross-sectional elevation view of the result of an operation in the method of FIG. 2, wherein a second trench is etched and an SBD material is deposited; and

FIG. 3D is a cross-sectional elevation view of the result of an operation in the method of FIG. 2, wherein electrical terminals are provided.

The figures are not intended to limit the examples to the specific details depict. The drawings are not necessarily to scale.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples. The illustrations presented herein are not meant to be actual views of any particular method, system, device, or structure, but are merely idealized representations that are employed to describe the examples of the present disclosure. Similar structures or components in the various drawings may retain the same or similar numbering for the convenience of the reader; however, any similarity in numbering does not necessarily mean that the structures or components are necessarily identical in size, composition, configuration, or any other property. Terms of relative location and direction (e.g., above, below, left, right, upper, lower) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation. It will be readily understood that the components of the examples as generally described herein and illustrated in the drawings could be arranged and designed in a wide variety of different configurations. Thus, the following description of various examples is not intended to limit the scope of the present disclosure but is merely representative of various examples.

Examples concern a device including an integrated trench FET and an integrated trench SBD, and a method of making a device including an integrated trench FET and an integrated trench SBD. Broadly, examples physically and functionally integrate a trench FET and a trench SBD into a single, continuous structure. Examples advantageously provide the benefits of improved reverse conduction and lower cost, and the larger diode resulting from the trench structure is advantageously able to handle higher electrical current. The improved reverse conduction (i.e., the third quadrant performance), particularly of a SiC MOSFET, is desirable for next-generation compact power electronics. Integration of the SBD with an SiC MOSFET provides an efficient mechanism for avoiding bipolar degradation when the parasitic P-N body diode is opened. For example, if the forward voltage of the body diode of the MOSFET is three-and-one-half (3.5) volts (V), and the forward voltage of the SBD is one-and-on-half (1.5) V, then the forward voltage drop is reduced by two (2) V, resulting in lower forward voltage losses. Further, integrating the SBD rather than connecting a discrete SBD provides the advantages of using less space, lowering cost, and requiring fewer dies in the manufacturing process.

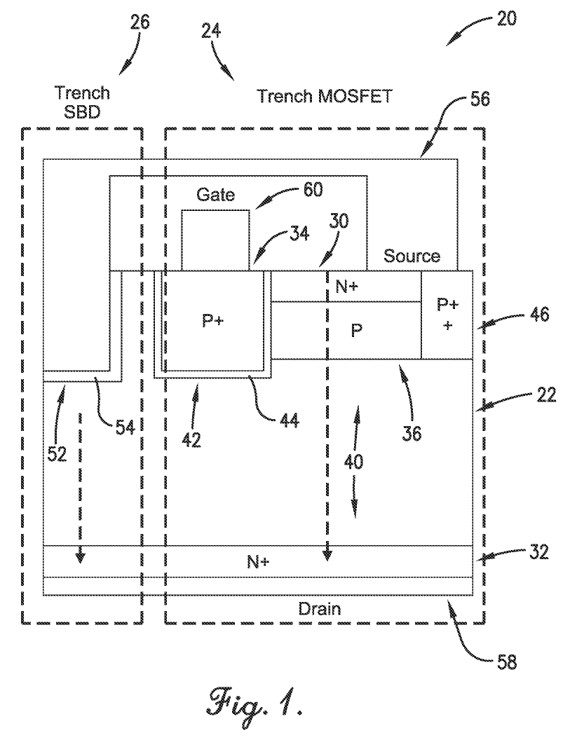

Referring to FIG. 1, an example of a device 20 is shown including a volume of semiconductor material 22 including a first end and a second end, an integrated trench MOSFET 24, and an integrated trench SBD 26. The volume of semiconductor material 22 may include N-type epitaxial semiconductor material. The integrated trench MOSFET 24 may include a source 30 located at the first end of the semiconductor material 22, a drain 32 located at the second end and opposite the source 30, a gate 34, and a body 36. In some aspects of the device, the drain may be located elsewhere relative to the body of semiconductor material (e.g., at the first end of the volume of semiconductor material). The source 30 may be constructed from or include an N+ material and provide an entrance for the majority charge carriers. The drain 32 may be constructed from or include an N+ substrate material and provide an exit for the majority of charge carriers. A channel 40 may be provided by a region of the semiconductor material 22 between the source 30 and the drain 32 through which the majority charge carriers move, i.e., through which electrical current flows. The gate 34 may be constructed from or include a doped polysilicon material, and may cooperate with the body 36 to facilitate control over the flow of charge carriers through the channel 40. The gate 34 may be located in a first or MOSFET trench 42 etched or otherwise created in the first end of the volume of semiconductor material 22 adjacent to the source 30. The first trench 42 may include a trench bottom and laterally spaced first and second sides extending between the bottom and the first end of the volume of semiconductor material 22, although other trench shapes are with the ambit of some aspects of the device. The first side of the first trench 42 may be spaced apart but adjacent the SBD 26. The first trench 42 may be lined with a thickness of a dielectric material 44, or gate oxide, such as SiO2. The dielectric material 44 lines the bottom and first and second sides of the trench 42. The body 36 may be constructed from or include a P-type material and have a P++ contact 46, and may cooperate with the gate 34 to control the current flow through the channel 40 between the source 30 and the drain 32. The source 30, body 36, and body contact 46 may be adjacent the second side of the first trench 42, such that the source 30, body 36, and body contact 46 are on the opposite side of the first trench 42 than the SBD 26.

The integrated trench SBD 26 may be generally located at the first end of the semiconductor material 22 adjacent to and spaced apart from the trench MOSFET 24, thereby physically and functionally integrating them into the single, continuous structure of the device 20. The trench SBD 26 may include a second or SBD trench 52 and an SBD material 54. The second trench 52 may be etched or otherwise created in the volume of semiconductor material 22 adjacent to and spaced apart from the gate 34 of the trench MOSFET 24. The second trench 52 may include a trench bottom and laterally spaced first and second sides extending between the bottom and the first end of the volume of semiconductor material 22, although other trench shapes are with the ambit of some aspects of the device. The second side of the second trench 52 may be spaced apart but adjacent to the first side of the first trench 42. At least some part of the SBD material 54 may be located within the second trench 52 and in contact with the volume of semiconductor material 22. The SBD material may occupy a first portion of the second trench 52 so that a remaining portion of the second trench is defined (for purposes described below). More particularly, the SBD material 54 may line the second trench 52 similar to how the dielectric material 44 lines the first trench 42. In other words, the SBD material 54 may line the bottom and/or the second side of the second trench 52. The SBD material 54 may be or include substantially any suitable material, such as aluminum, titanium, molybdenum, platinum, chromium, tungsten, or combinations thereof. The first or MOSFET trench 42 and the second or SBD 52 trench may extend an equal length or different lengths from the first end of the volume of semiconductor material 22.

A first electrical terminal 56 may be provided electrically connecting the source 30, the body 36 via the body contact 46, and the trench SBD 26. The first electrical terminal may extend into the SBD trench 52. In the example device 20, any remaining portion of the second trench 52 not occupied by the SBD material 54 is filled by the first electrical terminal 56. In some examples of the device 20, the first electrical terminal 56 may be formed of the SBD material. Yet further, according to certain examples of the device 20, the SBD material 54 and the first electrical terminal 56 may be integrally formed as a single, unitary body. Further, a second electrical terminal 58 may be provided on the drain 32, and a third electrical terminal 60 may be provided on the gate 34. The electrical terminals facilitate applying various voltages, as described below.

In operation, when a voltage, Vgs, is applied between the source 30 and the gate 34, the generated electric field creates an inversion layer at the semiconductor-dielectric interface. The inversion layer provides the channel 40 through which electrical current can flow when another voltage, Vds, is applied between the source 30 and the drain 32. More specifically, Vgs controls the width of the depletion region at the P-N junction where the charge carriers of the P- and N-type materials diffuse into each other, which "depletes" the available concentrations of majority charge carrier in each material, and thereby controls the current, Id, from the drain 32 to the source 30. In the present examples, the integrated trench SBD 26 is larger than conventional SBDs as a result of its trench structure and therefore advantageously able to handle higher electrical current.

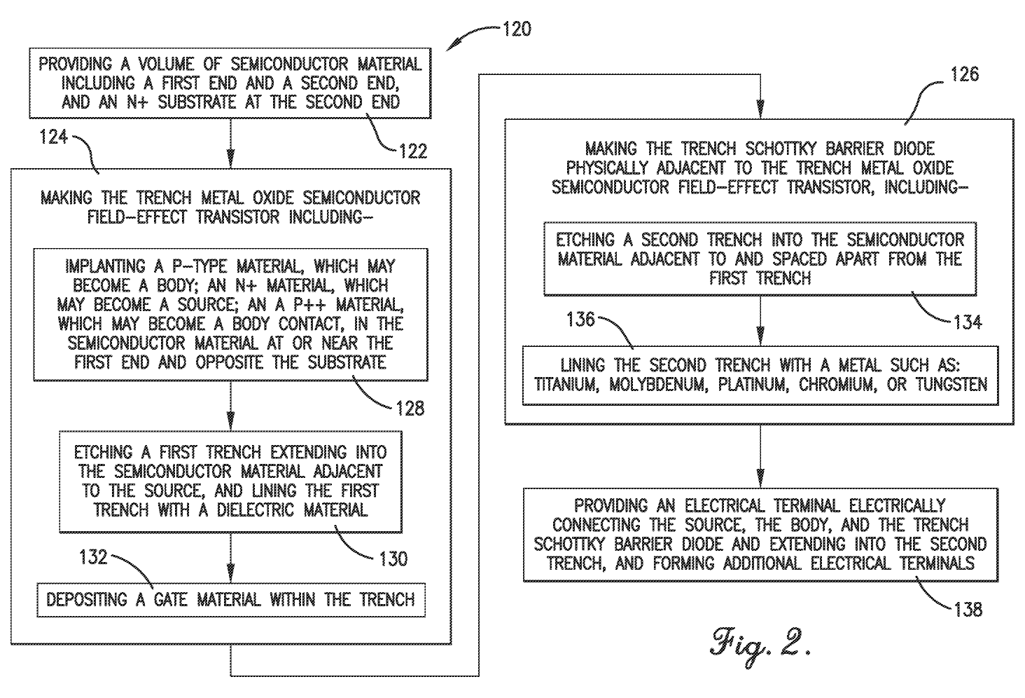

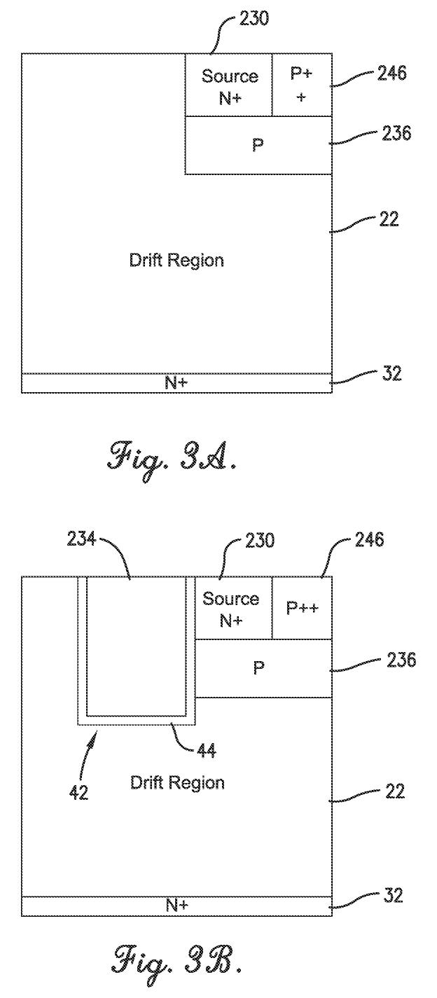

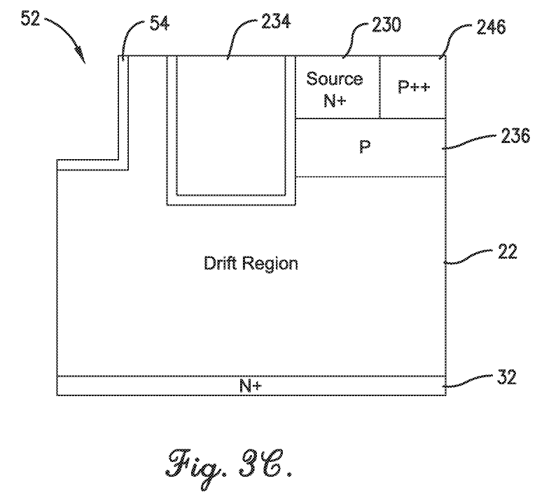

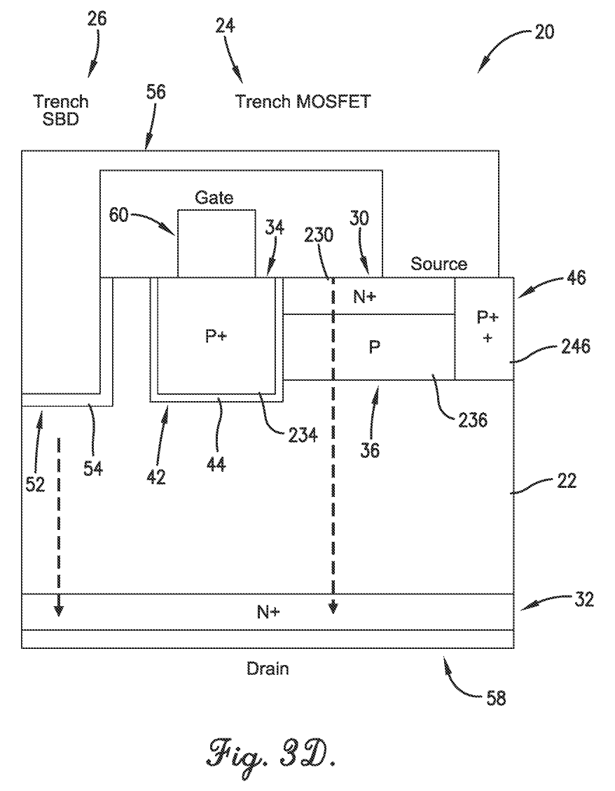

Referring to FIG. 2, an example of a method 120 of manufacturing a device, such as the example device 20 described above, including an integrated trench MOSFET 22 and an integrated trench SBD 24, may include the operations set forth below. Reference is made to the example device 20 of FIG. 1, and to example results of certain operations of the method shown in FIGS. 3A-3D. Making the device 20 may include providing a volume of semiconductor material 22 including a first end and a second end, and an N+ substrate 32 at the second end, as shown in 122 and seen in FIG. 3A. The volume of semiconductor material may include an N-type epitaxial semiconductor material. Making the device may further include making the integrated trench MOSFET 24, as shown in 124, and making the integrated trench SBD 26, as shown in 126.

Making the integrated trench MOSFET 24 may include implanting or otherwise providing a P-type material 236, which may become a body 36; an N+ material 230, which may become a source 30; and a P++ material 246, which may become a body contact 46, in the semiconductor material 22 at or near the first end, opposite the substrate 32, wherein the substrate 32 may become a drain, as shown in 128 and also seen in FIG. 3A. A region of the semiconductor material between the N+ source material 230 and the N+ drain substrate 32 may become a channel 40. A first or MOSFET trench 42 may be etched into the semiconductor material 40 adjacent to the N+ source material 230, and the first trench 42 may be lined with a dielectric material 44, or gate oxide, such as SiO2, as shown in 130 and seen in FIG. 3B. A doped polysilicon material 234, which may become a gate 34, may be deposited or otherwise provided in the first trench 42, as shown in 132 and also seen in FIG. 3B.

Making the integrated trench SBD 26 may include etching a second or SBD trench 52 into the semiconductor material 22 at or near the first end of the semiconductor material 22 and generally adjacent to and spaced apart from the first trench 42 of the trench MOSFET 24, as shown in 134 and seen in FIG. 3C. At least portions of the second trench 52 may be lined with an SBD material 54, which may be substantially any suitable SBD material, such as aluminum, titanium, molybdenum, platinum, chromium, tungsten, or combinations thereof, as shown in 136 and also seen in FIG. 3C. The first or MOSFET trench 42 and the second or SBD trench 52 may be etched to extend an equal length or different lengths from the first end of the volume of semiconductor material 22.

Making the device 20 may further include providing a first electrical terminal 56 that electrically connects the source 30, the body 36 via the body contact 46, and the trench SBD 26 and that extends into and fills the SBD trench 52; a second electrical terminal 58 on the drain 32; and a third electrical terminal 60 on the gate 34, as shown in 138 and seen in FIG. 3D, for applying appropriate voltages, as described above.

Additional processing may occur as desired.

Although described herein with regard or in relation to one or more particular kinds of electronic devices (e.g., junction field-effect transistors, metal oxide semiconductor field-effect transistors), the technology may be more broadly applicable to one or more other kinds of electronic devices as well. One with ordinary skill in the art will recognize that the technology described herein may, when applicable, be implemented in enhancement mode or depletion mode. Further, the technology described herein may, when applicable, be implemented as an N-channel or P-channel device, wherein, in general, regions that are N-doped or P-doped in N-channel implementations may be, respectively, P-doped or N-doped in P-channel implementations. Additionally, the various example materials identified herein may, in some aspects, be replaced or supplemented with substantially any other suitable material. For example, gate material may include polysilicon, a metal or alloy of metals, or other suitable material; gate oxide or dielectric may include silicon dioxide, aluminum oxide, hafnium dioxide, silicon nitride, or other suitable material; and semiconductor material may include silicon carbide, gallium nitride, zinc oxide, or other suitable material.

Additionally, in general, unless otherwise specified or unless one with ordinary skill in the art would understand otherwise, doping concentrations for contact implants may be approximately between ten to the power of eighteen (10^18) and ten to the power of twenty two (10^22); doping concentrations for channel and threshold forming implants may be approximately between ten to the power of sixteen (10^16) and ten to the power of seventeen (10^17); doping concentrations for shielding implants may be approximately between ten to the power of seventeen (10^17) and ten to the power of nineteen (10^19); and doping concentrations for conductivity improvement implants (e.g., N- doping in the junction field-effect transistor neck region of a metal oxide semiconductor field-effect transistor) may be approximately between ten to the power of sixteen (10^16) and ten to the power of seventeen (10^17). Relatedly, a structure or region may contain two or more different doping doses. For example, one with ordinary skill in the art will recognize that some P-wells may contain a lower dose P-well portion and a higher dose unclamped inductive switching portion.

It will be appreciated that the sides of the illustrated volume of semiconductor material are defined herein merely as an example, and may in various examples represent only a portion of semiconductor material relative to the illustrated device. In practice, the volume of semiconductor may extend laterally (leftward and rightward when viewing FIG. 1) beyond the bounds illustrated in the drawings to present additional semiconductor material in which additional devices may be provided. (The semiconductor material may similarly extend inwardly or outwardly (relative to the lateral or cross-sectional direction depicted in FIG. 1) to present additional devices in a direction transverse to the lateral direction.) Such additional devices may be FETs (which may be similarly or alternatively constructed to the illustrated device 20) or may be entirely different devices providing different operations or functions than the illustrated device. In other words, in practice, the illustrated device may be just one of numerous devices spaced laterally and transversely within a single, integrally formed component, such as a wafer (not shown).

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

1. A semiconductor device comprising:
a volume of semiconductor material including a first end and a second end;
an integrated trench field-effect transistor including –
a source located at the first end of the volume of semiconductor material,
a drain,
a body located adjacent to the source,
a body contact located adjacent to the body,
a first trench extending into the first end of the volume of semiconductor material, and
a gate located within the first trench;
an integrated trench Schottky barrier diode located at the first end of the volume of semiconductor material adjacent to and spaced apart from the integrated trench field-effect transistor, the integrated trench Schottky barrier diode including –
a second trench extending into the semiconductor material adjacent to and spaced apart from the gate,
a Schottky material lining at least part of the second trench; and
a first electrical terminal electrically connecting the source, the body via the body contact, and the integrated trench Schottky barrier diode,
the first electrical terminal extending into the second trench.

2. The device of claim 1,
the Schottky material and the first electrical terminal being integrally formed.

3. The device of claim 1,
the Schottky material occupying a first portion of the second trench,
the first electrical terminal filling the remaining portion of the trench.

4. The device of claim 1,
the first trench including a bottom and first and second spaced apart sides that extend between the bottom and the first end of the volume of semiconductor material,
the integrated trench field-effect transistor including a dielectric material lining the bottom and sides of the first trench.

5. The device of claim 1,
the second trench including a bottom and first and second spaced apart sides that extend between the bottom and the first end of the volume of semiconductor material,
the Schottky material lining the bottom and one of the sides of the second trench.

6. The device of claim 1,
the first trench including a bottom and first and second spaced apart sides that extend between the bottom and the first end of the volume of semiconductor material,
the first side of the first trench being spaced apart but adjacent the second trench,
the source, body, and body contact being located adjacent the second side of the first trench.

7. The device of claim 6,
the second trench including a bottom and first and second spaced apart sides that extend between the bottom and the first end of the volume of semiconductor material,
the second side of the second trench being spaced apart but adjacent the first side of the first trench,
the Schottky material lining the second side of the second trench.

8. The device of claim 7,
the integrated trench field-effect transistor including a dielectric material lining the first side the first side of the first trench.

9. The device of claim 8,
the dielectric material lining the bottom and the second side of the first trench,
the Schottky material lining the bottom of the second trench.

10. The device of claim 7,
the Schottky material lining the bottom of the second trench,
the first contact filling the remaining portion of the second trench.

11. The device of claim 1, wherein –
the volume of semiconductor material includes an N-type epitaxial semiconductor material,
the source includes an N+ material,
the drain includes an N+ substrate material,
the body includes a P-type material,
the body contact includes a P++ material, and
the gate includes a doped polysilicon material.

12. The device of claim 1, wherein the Schottky material is selected from the group consisting of: aluminum, titanium, molybdenum, platinum, chromium, tungsten, and combinations thereof.

13. The device of claim 1, comprising –
a second electrical terminal provided on the gate; and
a third electrical terminal provided on the drain.

14. The device of claim 1, wherein the first trench and the second trench extend an equal length from the first end of the volume of semiconductor material.

15. A method of making a device including an integrated trench field-effect transistor and an integrated trench Schottky barrier diode, the method comprising:
providing a volume of semiconductor material including a first end and a second end;
making the integrated trench field-effect transistor including –
providing a source at the first end of the volume of semiconductor material,
providing a drain,
providing a body located adjacent to the source,
providing a body contact adjacent to the body,
etching a first trench extending into the first end of the volume of semiconductor material, and
providing a gate within the first trench;
making the integrated trench Schottky barrier diode located at the first end of the volume of semiconductor material adjacent to and spaced apart from the integrated trench field-effect transistor, the operation of making the integrated trench Schottky barrier diode including –
etching a second trench extending into the semiconductor material adjacent to and spaced apart from the gate, and
lining at least part of the second trench with a Schottky material; and
providing an electrical terminal electrically connecting the source, the body via the body contact, and the integrated trench Schottky barrier diode,
the operation of providing the electrical terminal including extending the electrical terminal into the second trench.

16. The method of claim 15,
the operation of etching the first and second trenches including extending the first and second trenches an equal length from the first end of the volume of semiconductor material.

17. The method of claim 15,
the step of etching the first trench including forming a trench bottom and first and second spaced apart trench sides that extend between the trench bottom and the first end of the volume of semiconductor material, with the first trench side being spaced apart but adjacent the second trench,
the source, body, and body contact being located adjacent the second side of the first trench.

18. The method of claim 17,
the step of etching the second trench including forming a trench bottom and first and second spaced apart trench sides that extend between the trench bottom and the first end of the volume of semiconductor material, with the second trench side of the second trench being spaced apart but adjacent the first trench side of the first trench,
the step of lining the second trench with the Schottky material including lining the second trench side of the second trench.

19. The method of claim 18,
the step of making the integrated trench field-effect transistor including lining the first trench side of the first trench with a dielectric material.

20. The method of claim 15,
the Schottky material occupying a first portion of the second trench,
the operation of providing the electrical terminal including filling the remaining portion of the second trench with the electrical terminal.
